(19) United States
(12) Patent Application Publication
(10) Pub. No.: US 2026/0173857 A1
(43) Pub. Date: Jun. 18, 2026

(54) GRAPHENE CAP LAYER WITH COMPOSITE ETCH STOP LAYER

(71) Applicant: International Business Machines Corporation, Armonk, NY (US)

(72) Inventors: Yann Mignot, Slingerlands, NY (US); Son Nguyen, Schenectady, NY (US); Kishore Natarajan, Albany, NY (US); Sang-Kee Eah, Watervliet, NY (US)

(21) Appl. No.: 18/983,869

(22) Filed: Dec. 17, 2024

(51) Int. Cl. H10W 20/44

(52) U.S. Cl. CPC H10W 20/4462

(57) ABSTRACT

A semiconductor structure includes a graphene cap layer disposed on a top surface of one or more conductive metal lines, and a composite etch stop layer disposed on the graphene cap layer.

### BACKGROUND

Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor structure includes a graphene cap layer disposed on a top surface of one or more conductive metal lines, and a composite etch stop layer disposed on the graphene cap layer.

In another illustrative embodiment, a semiconductor structure includes a first dielectric layer having a conductive metal trench disposed therein, a first graphene cap layer disposed on a portion of a top surface of the conductive metal trench, a first composite etch stop layer disposed on the first graphene cap layer, a second dielectric layer disposed on the first dielectric layer, the second dielectric layer having a conductive metal via connected to the conductive metal trench, a second graphene cap layer disposed on a top surface of the second conductive metal via, and a second composite etch stop layer disposed on the second graphene cap layer.

In yet another illustrative embodiment, a method for forming a semiconductor structure includes forming a graphene cap layer on a top surface of a conductive metal line, and forming a composite etch stop layer on the graphene cap layer.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 depicts a cross-sectional view illustrating a semiconductor structure during an intermediate step of a method of fabricating a semiconductor structure, according to an illustrative embodiment.

FIG. 2 is a cross-sectional view of the semiconductor structure following formation of a first graphene cap layer on a top surface of first conductive metal lines, according to an illustrative embodiment.

FIG. 3 is a cross-sectional view of the semiconductor structure following formation of a first composite etch stop layer, according to an illustrative embodiment.

FIG. 4 is a cross-sectional view of the semiconductor structure following formation of a dual damascene structure in a dielectric layer, according to an illustrative embodiment.

FIG. 5 is cross-sectional view of the semiconductor structure following formation of second conductive metal lines in the dual damascene structure, followed by formation of a second graphene cap layer on a top surface of the second conductive metal lines, followed by formation of a second composite etch stop layer, according to an illustrative embodiment.

### DETAILED DESCRIPTION

This disclosure relates generally to semiconductor devices, and more particularly to semiconductor structures having a graphene cap layer disposed on a top surface of conductive metal lines, and a composite etch stop layer disposed on the graphene cap layer, and methods for their fabrication. However, it is to be understood that embodiments of the present disclosure are not limited to the illustrative methods, apparatus, systems and devices but instead are more broadly applicable to other suitable methods, apparatus, systems and devices.

Detailed embodiments of the semiconductor structures and methods are disclosed herein. The method steps described below do not form a complete process flow for manufacturing integrated circuits, such as semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “lateral,” “lateral side,” “lateral surface” refers to a side surface of an element (e.g., a layer, opening, etc.), such as a left or right side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

As used herein, the term dual damascene structure may refer to a via or line formed from a dual damascene process.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include, but are not limited to, physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film’s electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s). Other suitable techniques, such as sidewall image transfer (SIT), self-aligned double patterning (SADP), self-aligned quadruple patterning (SAQP), self-aligned multiple patterning (SAMP) and self-aligned litho etch (SALELE) can be used to etch or pattern.

In general, conventional metal interconnects employ metals such as copper (Cu) as the conductor in a dielectric. Damage to the dielectric can occur during patterning of the features in the dielectric, and plasma damage to the dielectric can occur during metallization. Such dielectric damage is undesirable as it leads to a high capacitance, especially with reduced scale interconnects. Via chamfering and via bowing can also occur during patterning of the features in the dielectric. Chamfering refers to a widening or beveling of the top profile of the via, while via bowing refers to widening of the via CD that causes the via side wall to form a bow shape. Chamfering is undesirable as it degrades Cu fill and reliability. Thus, a solution is needed to form metal interconnects without via chamfering.

Illustrative embodiments overcome the foregoing drawbacks by forming a graphene cap layer disposed on a top surface of conductive metal lines, and a composite etch stop layer disposed on the graphene cap layer. In addition, this configuration allows for formation of a dual damascene structure with an improved chamfer profile.

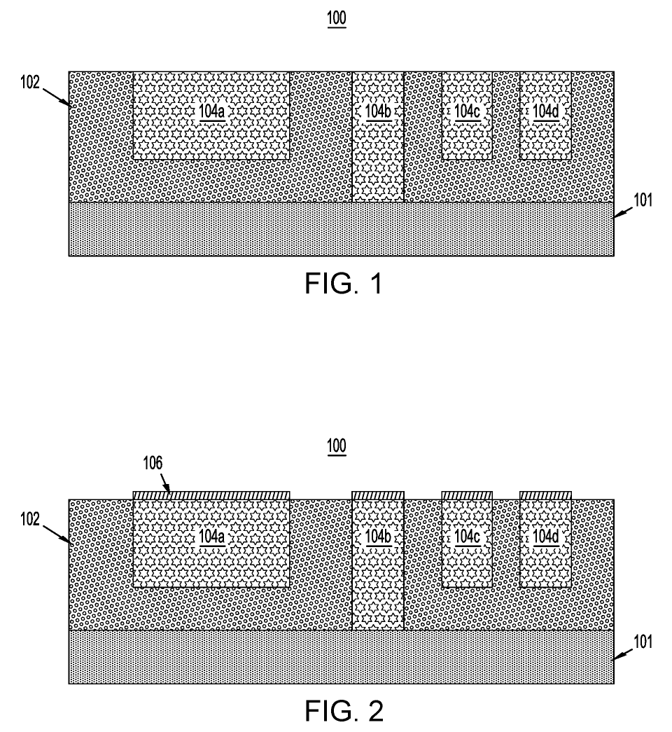

Referring now to the drawings in which like numerals represent the same or similar elements, FIGS. 1-5 illustrate various processes for fabricating semiconductor structures with a graphene cap layer disposed on a top surface of conductive metal lines, and a composite etch stop layer disposed on the graphene cap layer. Note that the same reference numeral (100) is used to denote the semiconductor structure through the various intermediate fabrication stages illustrated in FIGS. 1-5. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1-5 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

Referring now to FIG. 1, a semiconductor structure 100 is shown during an intermediate step of a method of fabricating a metal interconnect structure. The semiconductor structure 100 includes a substrate 101 having a dielectric layer 102 with conductive metal lines including, for example, a conductive metal trench 104a and conductive metal vias 104b to 104d. The substrate 101 can be any wafer, semiconductor wafer, partially fabricated integrated circuit, printed circuit board, display screen, or other appropriate workpiece. In some implementations, the substrate 101 is a semiconductor substrate such as a silicon (Si) substrate.

The dielectric layer 102 may be formed of any suitable isolating dielectric material, such as an interlevel dielectric (ILD) layer composed of, for example, SiO₂, SiOC, SiON, etc. The conductive metal trench 104a and the conductive metal vias 104b to 104d can be of any suitable electrically conductive material. In some embodiments, an electrically conductive material includes, for example, a conductive metal such as tungsten (W), aluminum (Al), copper (Cu), cobalt (Co), ruthenium (Ru), molybdenum (Mo), or any other suitable electrically conductive material. If desired, a metallic liner can be combined with the and metallic liner combined or not with specific metal for optimum conductivity for optimum conductivity.

Referring now to FIG. 2, the semiconductor structure 100 is shown following formation of graphene cap layers 106 on a top surface of the conductive metal trench 104a and the conductive metal vias 104b to 104d, according to an embodiment of the invention. The term “graphene” as used herein includes carbon-based material that may have a mixture of sp2 and sp3 hybridized carbon. In some embodiments, graphene includes carbon having only sp2 bonds. In some embodiments, graphene includes carbon having at least about 50% sp2 bonds, or at least about 60% sp2 bonds, or at least about 70% sp2 bonds, or at least about 80% sp2 bonds, or at least about 90% sp2 bonds, or about 100% sp2 bonds. In some embodiments, graphene includes a monolayer of carbon atoms arranged in a hexagonal lattice. In some embodiments, graphene includes one or more monolayers of carbon atoms bonded to carbon atoms, including bilayers of carbon bonded to carbon, trilayers of carbon bonded to carbon, and thicker variations thereof. In some embodiments, graphene includes a monolayer of elemental carbon. It will be understood that while some embodiments of graphene may have mostly sp2 hybridized carbons, in some embodiments, a mixture of sp2 and sp3 hybridized carbons may be present. In some embodiments, graphene may include mostly carbon, with little to no dopants or other atoms therein. In some embodiments, graphene may have a lattice structure. In some embodiments, graphene is 100% carbon. In some embodiments, graphene is dopant-free. In some embodiments, graphene is hydrogen-free. In some embodiments, graphene is hydrogen-free and includes carbon having at least about 90% sp2 bonds, and up to about 100% sp2 bonds.

The graphene cap layers 106 can be formed by selectively depositing graphene on a top surface of respective conductive metal lines including the conductive metal trench 104a and the conductive metal vias 104b to 104d using such conventional deposition techniques as, for example, ALD, CVD, PVD and the like, with and without passivation layers in non-selective surfaces.

In some embodiments, depositing the graphene cap layers 106 on the top surface of the conductive metal trench 104a and the conductive metal vias 104b to 104d of the substrate 101 may be accomplished by remote hydrogen plasma CVD and introduction of a carbon-containing precursor. The carbon-containing precursor may be activated by the remote hydrogen plasma. In some embodiments, depositing the graphene cap layers 106 on the top surface of the conductive metal trench 104a and the conductive metal vias 104b to 104d of the substrate 101 may be accomplished using any suitable deposition technique such as thermal CVD or PECVD or remoted plasma CVD. A remote hydrogen plasma CVD method may deposit the graphene cap layers 106 at low temperatures that are compatible with semiconductor processing. In some embodiments, the graphene cap layers 106 may be deposited at temperatures of about 200°C to about 500°C. In some embodiments, the graphene cap layers 106 may be deposited at temperatures of less than or equal to about 400°C when the conductive metal for the conductive metal trench 104a and the conductive metal vias 104b to 104d is copper. The temperatures can be higher for other conductive metals such as ruthenium.

When depositing the graphene cap layers 106 using remote hydrogen plasma CVD, a hydrocarbon precursor is flowed to the top surface of the conductive metal trench 104a and the conductive metal vias 104b to 104d of the substrate 101 and hydrogen radicals are generated in a remote plasma source upstream of the hydrocarbon precursor flow. The hydrogen radicals interact with the hydrocarbon precursor to activate the hydrocarbon precursor downstream from the remote plasma source, and the activated hydrocarbon precursor interacts with the top surface of the conductive metal trench 104a and the conductive metal vias 104b to 104d to cause the graphene cap layers 106 to deposit. In some embodiments, the hydrocarbon precursor includes an alkene group or alkyne group with double bond and triple bonds such as, for example, 2 carbon hydrocarbon precursors such as ethylene and ethyne.

In some embodiments, the graphene cap layers 106 can have a thickness ranging from about 1 nanometer (nm) to about 3 nm.

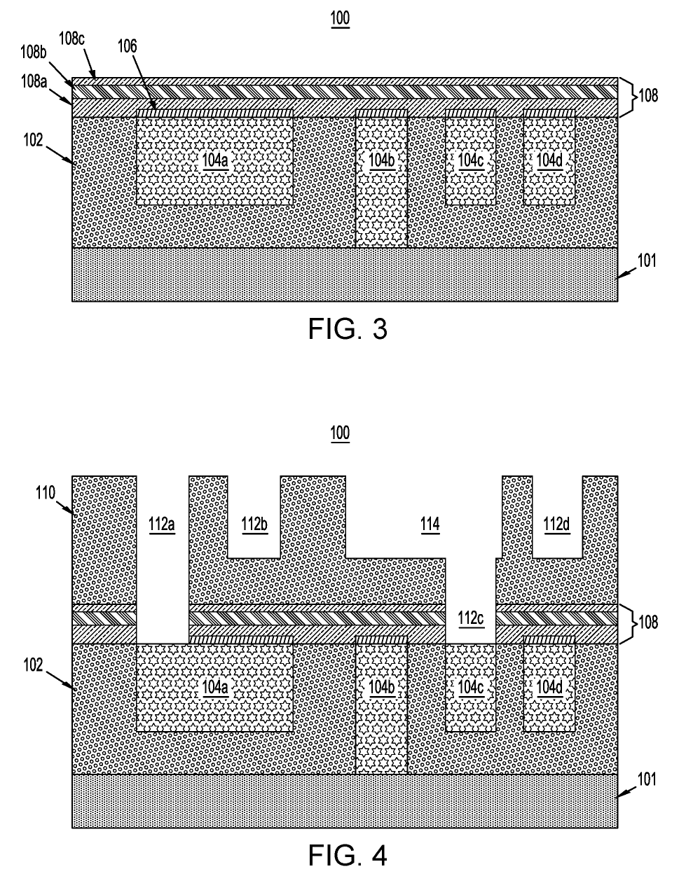

Referring now to FIG. 3, the semiconductor structure 100 is shown following formation of composite etch stop layer 108 on the graphene cap layers 106, according to an embodiment of the invention. In some embodiments, the composite etch stop layer 108 include a bilayer etch stop layer. In some embodiments, the composite etch stop layer 108 include a trilayer etch stop layer. For example, the composite etch stop layer 108 can include a first etch stop layer 108a, a second etch stop layer 108b and a third etch stop layer 108c. In some embodiments, the first etch stop layer 108a and the third etch stop layer 108c are composed of the same material and the second etch stop layer 108b is composed of a material different than the material of the first etch stop layer 108a and the third etch stop layer 108c.

In some embodiments, the first etch stop layer 108a and the third etch stop layer 108c can be a metal oxide. Suitable metal oxides include, for example, aluminum oxide, hafnium oxide, zirconium oxide, yttrium oxide, zinc oxide, titanium oxide, or combinations thereof. In some embodiments, the first etch stop layer 108a and the third etch stop layer 108c include aluminum oxide. In some embodiments, the first etch stop layer 108a and the third etch stop layer 108c may have a thickness of about 0.4 nm to about 6 nm.

In some embodiments, the second etch stop layer 108b can be a silicon-based carbon layer such as SiC, or a silicon-based oxide layer such as SiCo or SiCNO or a silicon-based nitride layer such as SiCN. In some embodiments, the second etch stop layer 108b may have a thickness of about 0.4 nm to about 8 nm. In some embodiments, the second etch stop layer 108b will have a thickness greater than the thickness of the first etch stop layer 108a and the third etch stop layer 108c.

In some embodiments, the composite etch stop layer 108 is deposited over the graphene cap layers 106 using a thermal deposition technique such as thermal ALD or thermal CVD.

Referring now to FIG. 4, the semiconductor structure 100 is shown following formation of a dual damascene structure in a dielectric layer 110, according to an embodiment of the invention. The semiconductor structure 100 further includes the dielectric layer 110 over the composite etch stop layer 108. In some embodiments, the dielectric layer 110 includes any suitable dielectric material such as low-k dielectric, silicon oxide, undoped silicon carbide, doped silicon carbide, or combinations thereof. In some embodiments, the dielectric layer 110 can be an ILD layer as discussed above for the dielectric layer 102. The composite etch stop layer 108 may have an etch selectivity different than the dielectric layer 110. For example, the composite etch stop layer 108 may have an etch resistance equal to or greater than ten times that of an etch resistance of the dielectric layer 110 when one or more recesses are formed in the dielectric layer 110 as discussed below. The high selectivity of the composite etch stop layer 108 when etching the dielectric layer 110 enables a better stop on top of the composite etch stop layer 108 with minimal recess in the composite etch stop layer 108 with a better CD control resulting in a straighter bottom profile helping the improve the chamfer angle. The dielectric layer 110 can be deposited using any conventional deposition technique such as ALD, CVD, PVD, etc.

Next, multi patterning lithographic and etching steps are carried out for etching openings 112a, 112b, 112c, 112d and 114 at one or more locations through the dielectric layer 110. For example, lithographic patterning techniques combined with RIE etching steps using a dual damascene process will create the openings 112a, 112b, 112c, 112d and 114 through the dielectric layer 110. In some embodiments, a single etch or multiple etching can be used to provide the openings 112a, 112b, 112c, 112d and 114. The etch or multiple etches can include a dry etch process, a chemical wet etch process, or any combination thereof. When a dry etch is used, the dry etch can be an RIE process, a plasma etch process, ion beam etching or laser ablation. The patterned stack used for the dual damascene is generally composed of a metal hardmask such as TiN or WDC (tungsten dope carbon) and photoresist material that are removed after the opening of dielectric layer 110 with, for example, an etch plasma composed of O₂, CO/CO₂ or N₂/H₂ for example for the photoresist. The hardmask is removed by a wet etch or later in the process by CMP during the metallization of the openings 112a, 112b, 112c, 112d and 114. In some embodiments, the openings 112a, 112b, 112c, 112d and 114 can be formed in the dielectric layer 110 by, for example, using RIE plasma composed of CF₄, C₄F₈, C₄F₆, CH₂F₂ or any other CFx elements with other gases to achieve desired profile.

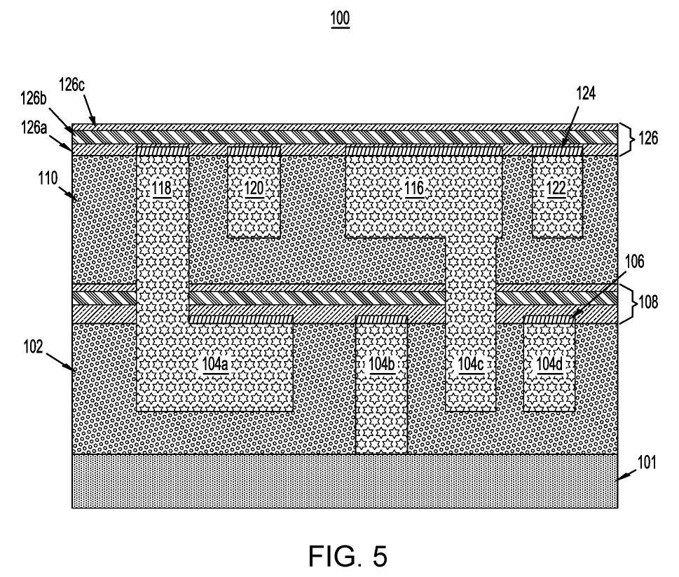

Referring now to FIG. 5, the semiconductor structure 100 is shown following formation of conductive metal lines including, for example, conductive metal trenches 116, 120, and 122 and conductive metal via 118 and the conductive metal via connecting the conductive metal trench 116 to the conducting metal via 104c in the dual damascene structure, followed by formation of graphene cap layers 124 on a top surface of the conductive metal trenches 116, 120 and 122 and the conductive metal via 118, followed by formation of a composite etch stop layer 126 disposed on the graphene cap layers 124, according to an embodiment of the invention.

In some embodiments, an electrically conductive material is deposited in the openings 112a, 112b, 112c, 112d and 114 shown in FIG. 4 to form the conductive metal trench 116 over the conductive via 104c with a conductive metal via connecting the conductive metal trench 116 to the conducting metal via 104c, the conductive metal via 118 over the conductive metal trench 104a, the conductive metal trench 120 and the conductive metal trench 122. In some embodiments, the electrically conductive material can be any of the conductive metals discussed above. If necessary, a planarization process such as CMP can be carried out after depositing the electrically conductive material.

The graphene cap layers 124 is then deposited on the conductive metal trenches 116, 120, and 122 and the conductive metal via 118. The material and deposition can be similar to that disclosed for the graphene cap layer 106. In some embodiments, the graphene cap layers 124 can have a thickness ranging from about 1 nm to about 3 nm.

The composite etch stop layer 126 is then deposited on the dielectric layer 110 and the graphene cap layers 124 using, for example, a thermal deposition technique such as thermal ALD or thermal CVD. In some embodiments, the composite etch stop layer 126 includes a bilayer etch stop layer. In some embodiments, the composite etch stop layer 126 includes a trilayer etch stop layer. For example, the composite etch stop layer 126 can include a first etch stop layer 126a, a second etch stop layer 126b and a third etch stop layer 126c. In some embodiments, the first etch stop layer 126a and the third etch stop layer 126c are composed of the same material and the second etch stop layer 126b is composed of a material different than the material of the first etch stop layer 126a and the third etch stop layer 126c.

In some embodiments, the first etch stop layer 126a and the third etch stop layer 126c can be a metal oxide. Suitable metal oxides include, for example, aluminum oxide, hafnium oxide, zirconium oxide, yttrium oxide, zinc oxide, titanium oxide, or combinations thereof. In some embodiments, the first etch stop layer 126a and the third etch stop layer 126c include aluminum oxide. In some embodiments, the first etch stop layer 126a and the third etch stop layer 126c may have a thickness of about 0.4 nm to about 6 nm.

In some embodiments, the second etch stop layer 126b can be a silicon-based carbon layer such as SiC, or a silicon-based oxide layer such as SiCo or SiCNO or a silicon-based nitride layer such as SiCN. In some embodiments, the second etch stop layer 126b may have a thickness of about 0.4 nm to about 8 nm. In some embodiments, the second etch stop layer 126b will have a thickness greater than the thickness of the first etch stop layer 126a and the third etch stop layer 126c.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a graphene cap layer disposed on a top surface of one or more conductive metal lines; and
a composite etch stop layer disposed on the graphene cap layer.

2. The semiconductor structure according to claim 1, wherein the composite etch stop layer comprises a bilayer composite etch stop layer.

3. The semiconductor structure according to claim 2, wherein the bilayer composite etch stop layer comprises a first layer disposed on the graphene cap layer and a second layer disposed on the first layer.

4. The semiconductor structure according to claim 3, wherein the first layer comprises a metal oxide and the second layer comprises a silicon-based carbon layer, a silicon-based oxide layer or a silicon-based nitride layer.

5. The semiconductor structure according to claim 3, wherein the first layer comprises aluminum oxide and the second layer comprises one of SiCO, SiCN, SiCNO or SiC.

6. The semiconductor structure according to claim 1, wherein the composite etch stop layer comprises a trilayer composite etch stop layer.

7. The semiconductor structure according to claim 6, wherein the trilayer composite etch stop layer comprises a first layer disposed on the graphene cap layer, a second layer disposed on the first layer and a third layer disposed on the second layer, wherein the first layer and the third layer are composed of a same material.

8. The semiconductor structure according to claim 7, wherein the first layer comprises a first metal oxide, the second layer comprises a silicon-based carbon layer, a silicon-based oxide layer or a silicon-based nitride layer and the third layer comprises a second metal oxide.

9. The semiconductor structure according to claim 7, wherein the first layer comprises aluminum oxide, the second layer comprises one of SiCO, SiCN, SiCNO or SiC and the third layer comprises aluminum oxide.

10. A semiconductor structure, comprising:
a first dielectric layer having a conductive metal trench disposed therein;
a first graphene cap layer disposed on a portion of a top surface of the conductive metal trench;
a first composite etch stop layer disposed on the first graphene cap layer;
a second dielectric layer disposed on the first dielectric layer, the second dielectric layer having a conductive metal via connected to the conductive metal trench;
a second graphene cap layer disposed on a top surface of the conductive metal via; and
a second composite etch stop layer disposed on the second graphene cap layer.

11. The semiconductor structure according to claim 10, wherein the conductive metal via connected to the conductive metal trench is a dual damascene structure.

12. The semiconductor structure according to claim 10, wherein the first graphene cap layer and the second graphene cap layer each have a thickness of from about 1 nanometer to about 3 nanometers.

13. The semiconductor structure according to claim 10, wherein the first composite etch stop layer comprises a first bilayer composite etch stop layer and the second composite etch stop layer comprises a second bilayer composite etch stop layer.

14. The semiconductor structure according to claim 13, wherein the first bilayer composite etch stop layer comprises a first layer disposed on the first graphene cap layer and a second layer disposed on the first layer, wherein the first layer comprises a metal oxide and the second layer comprises a silicon-based carbon layer, a silicon-based oxide layer or a silicon-based nitride layer, and the second bilayer composite etch stop layer comprises a third layer disposed on the second graphene cap layer and a fourth layer disposed on the third layer, wherein the third layer comprises a metal oxide and the fourth layer comprises a silicon-based carbon layer, a silicon-based oxide layer or a silicon-based nitride layer.

15. The semiconductor structure according to claim 14, wherein the first layer and the third layer each comprise aluminum oxide and the second layer and the fourth layer each comprise one of SiCO, SiCN, SiCNO or SiC.

16. The semiconductor structure according to claim 10, wherein the first composite etch stop layer comprises a first trilayer composite etch stop layer comprising a first layer disposed on the first graphene cap layer, a second layer disposed on the first layer and a third layer disposed on the second layer, wherein the first layer comprises a first metal oxide, the second layer comprises a silicon-based carbon layer, a silicon-based oxide layer or a silicon-based nitride layer and the third layer comprises a second metal oxide.

17. The semiconductor structure according to claim 16, wherein the first layer and the third layer each comprise aluminum oxide and the second layer comprises one of SiCO, SiCN, SiCNO or SiC.

18. The semiconductor structure according to claim 16, wherein the second composite etch stop layer comprises a second trilayer composite etch stop layer comprising a fourth layer disposed on the second graphene cap layer, a fifth layer disposed on the fourth layer and a sixth layer disposed on the fifth layer, wherein the fourth layer comprises a third metal oxide, the fifth layer comprises a silicon-based carbon layer, a silicon-based oxide layer or a silicon-based nitride layer and the sixth layer comprises a fourth metal oxide.

19. The semiconductor structure according to claim 18, wherein the fourth layer and the sixth layer each comprise aluminum oxide and the fifth layer comprises one of SiCO, SiCN, SiCNO or SiC.

20. A method for forming a semiconductor structure, comprising:
forming a graphene cap layer on a top surface of a conductive metal line; and
forming a composite etch stop layer on the graphene cap layer.
